(19) United States
(12) Patent Application Publication
(10) Pub. No.: US 2013/0286626 A1
(43) Pub. Date: Oct. 31, 2013

(54) CABLE MANAGEMENT DEVICE

(71) Applicant: INTERNATIONAL BUSINESS MACHINES CORPORATION, Armonk, NY (US)

(72) Inventors: WEI-TIEN CHEN, NEW TAIPEI CITY (TW); YULIANTI DARMANTO, NEW TAIPEI CITY (TW); CHIA-CHING HUANG, TAIPEI (TW); YU-KANG LIU, NEW TAIPEI CITY (TW); HUI-WEN TSAI, TAIPEI (TW)

(73) Assignee: INTERNATIONAL BUSINESS MACHINES CORPORATION, ARMONK, NY (US)

(21) Appl. No.: 13/873,386

(22) Filed: Apr. 30, 2013

(30) Foreign Application Priority Data
Apr. 30, 2012 (TW) 101115337

(51) Int. Cl. H05K 7/18

(52) U.S. Cl. CPC H05K 7/183
USPC 361/809; 211/183; 211/26.2

(57) ABSTRACT

A cable management device includes a device body, a connecting member, and an extension body. The device body includes a first cable management arm and a second cable management arm. The connecting member pivotally connects a first end of the first cable management arm and a first end of the second cable management arm to attain a first cable management configuration. The connecting member is removable from the first cable management arm and the second cable management arm. In response to removal of the connecting member, two opposing ends of the extension body are respectively connected to the first end of the first cable management arm and the first end of the second cable management arm to attain a second cable management configuration. The cable management device may be included in a rack assembly.

### CROSS-REFERENCE TO RELATED APPLICATION

This application claims priority under 35 U.S.C. § 119 to Taiwanese Patent Application No. 101115337, filed on Apr. 30, 2012, the entire text of which is specifically incorporated by reference herein.

### BACKGROUND

Various embodiments of the invention relate to cable management devices, and more particularly, to a cable management device adapted to be installed on an electrical equipment on a rack.

A rack-style server or other electrical equipment (e.g., Web-based communication products or storage apparatuses) stacked on and installed on a rack is usually equipped with two opposing sliding rail devices and thereby slidably installed in the rack such that the server or other electrical equipment may be withdrawn from the rack and maintained. For example, the rear end of a server is typically provided with a plurality of cables connected to a power source and adapted to transmit signals. Hence, the rear end of the server is usually provided with a cable management device for containing, holding, and managing the cables to facilitate the installation, withdrawal, and maintenance of the server.

Normally, the cable management device is of two types, namely a full out type and a half out type. The half out cable management device is usually used when the size of or the design for a rack chassis is significantly limited, or when the width of a server or other electrical equipment is large. The full out cable management device is usually used when a rack chassis has space to accommodate a large sliding rail.

### SUMMARY

Various embodiments of the invention provide a cable management device that provides various cable management configurations in accordance with different spatial arrangements inside a rack chassis. Specifically, various embodiments of the invention provide a flexible cable management device having a full out configuration and a half out configuration so as to serve both a full out purpose and a half out purpose.

Various embodiments of the invention further provide an electrical equipment rack assembly including such cable management device. The electrical equipment associated with the rack assembly may include a computer server, a Web-based communication product, or a storage apparatus.

A cable management device according to an embodiment of the invention includes a device body comprising a first cable management arm and a second cable management arm. The cable management device includes a removable connecting member. The connecting member pivotally connects a first end of the first cable management arm and a first end of the second cable management arm to attain a first cable management configuration. The cable management device further includes an extension body. In response to removal of the connecting member, two opposing ends of the extension body are respectively connected to the first end of the first cable management arm and the first end of the second cable management arm to attain a second cable management configuration.

According to a further embodiment of the invention, the extension body includes a third cable management arm and fourth cable management arm. In response to removal of the connecting member, an end of the third cable management arm is engaged with the first end of the first cable management arm via a first engaging device, and an end of the fourth cable management is engaged with the first end of the second cable management arm via a second engaging device.

According to a further embodiment of the invention, the first engaging device includes a first engaging hole and a first engaging post engaged with the first engaging hole. The first engaging hole and the first engaging post are interchangeably disposed at the first cable management arm and the third cable management arm, respectively. The second engaging device includes a second engaging hole and a second engaging post engaged with the second engaging hole. The second engaging hole and the second engaging post are interchangeably disposed at the second cable management arm and the fourth cable management arm, respectively.

According to a further embodiment of the invention, the cable management device is disposed between a first sliding rail device and an opposing second sliding rail device of a rack. Each of the first sliding rail device and the second sliding rail device includes a first track fixed to the rack and a second track slidably disposed on the first track. A second end of the first cable management arm and a second end of the second cable management arm are connected to the first track and the second track of the first sliding rail device, respectively, such that the device body unfolds or folds as the first sliding rail device (e.g., the second track of the first sliding rail device) protrudes forward or retracts backward.

According to a further embodiment of the invention, the cable management device includes a first installation element pivotally connected to the second end of the first cable management arm and engaged with the first track of the first sliding rail device. The cable management device includes a second installation element pivotally connected to the second end of the second cable management arm and engaged with the second track of the first sliding rail device.

An additional embodiment of the invention provides an electrical equipment rack assembly including an electrical equipment rack comprising a sliding rail device, an electrical equipment unit slidably disposed on the sliding rail device, and a cable management device connected to the electrical equipment unit and the sliding rail device. The cable management device includes a device body including a first cable management arm and a second cable management arm. The first cable management arm and the second cable management arm unfold or fold when the electrical equipment unit protrudes or retracts. The cable management device further includes a removable connecting member pivotally connecting a first end of the first cable management arm and a first end of the second cable management arm to attain a first cable management configuration. The cable management device further includes an extension body. In response to removal of the connecting member, two opposing ends of the extension body are respectively connected to the first end of the first cable management arm and the first end of the second cable management arm to attain a second cable management configuration.

According to a further embodiment of the invention, the sliding rail device includes a first sliding rail and an opposing second sliding rail. The cable management device is disposed between the first sliding rail and the sliding second rail. Each of the first sliding rail and the second sliding rail includes a first track fixed to the rack and a second track slidably disposed on the first track. A second end of the first cable management arm and a second end of the second cable management arm are connected to the first track and the second track of the first sliding rail, respectively. The second end of the second cable management arm is connected to the electrical equipment unit, such that the device body unfolds or folds as the first sliding rail (e.g., the second track of the first sliding rail) protrudes forward or retracts backward.

Reference throughout this specification to features, advantages, or similar language does not imply that all of the features and advantages that may be realized with the invention should be or are in any single embodiment of the invention. Rather, language referring to the features and advantages is understood to mean that a specific feature, advantage, or characteristic described in connection with an embodiment is included in at least one embodiment of the invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

The following description, the appended claims, and the embodiments of the invention further illustrate the features and advantages of the invention.

### BRIEF DESCRIPTION OF THE SEVERAL VIEWS OF THE DRAWINGS

In order that the advantages of various embodiments of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the various embodiments will be described and explained with additional specificity and detail through the use of the accompanying drawings.

FIG. 1 is a perspective schematic view of a cable management device, according to an embodiment of the invention.

FIG. 2 is a schematic view of a cable management device in a half out configuration, according to an embodiment of the invention.

FIG. 3 is a schematic view of an electrical equipment rack and a cable management device folded in a half out configuration, according to an embodiment of the invention.

FIG. 4 is a schematic view of an electrical equipment rack and a cable management device unfolded in a half out configuration, according to an embodiment of the invention.

FIG. 5 is a schematic view of an electrical equipment rack and a cable management device in a full out configuration, in which the cable management device is in an extended state, according to an embodiment of the invention.

### DETAILED DESCRIPTION

Various embodiments of the invention are described in detail as follows. The disclosed embodiments are only used for illustration. One skilled in the art should understand that there may be many modifications and variations within the scope of the various embodiments of the invention. While referring to the figures, the same reference numbers represent the same parts in all figures.

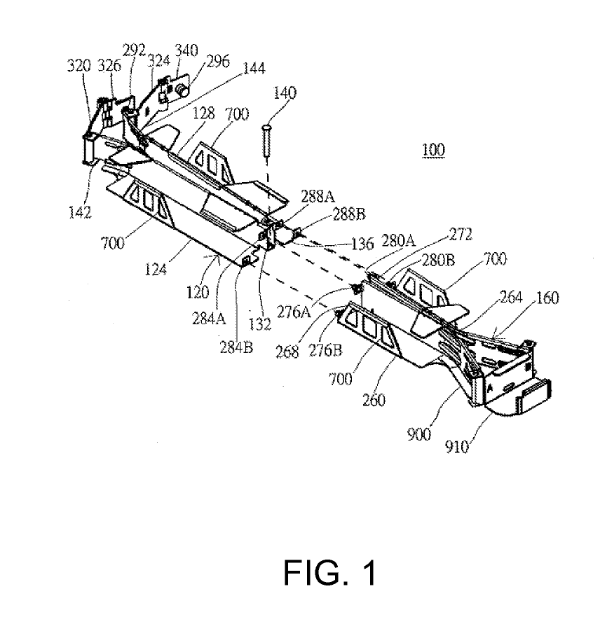

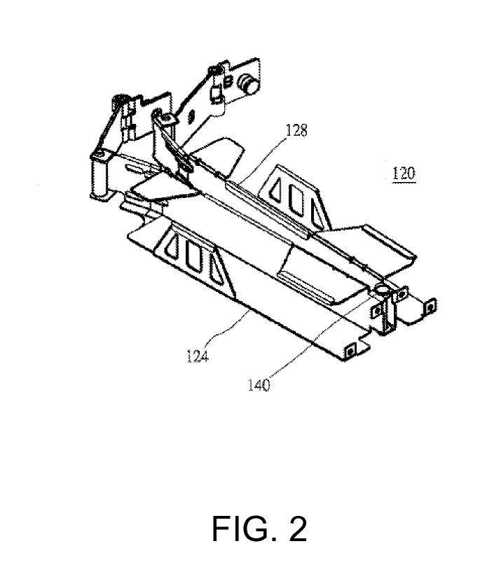

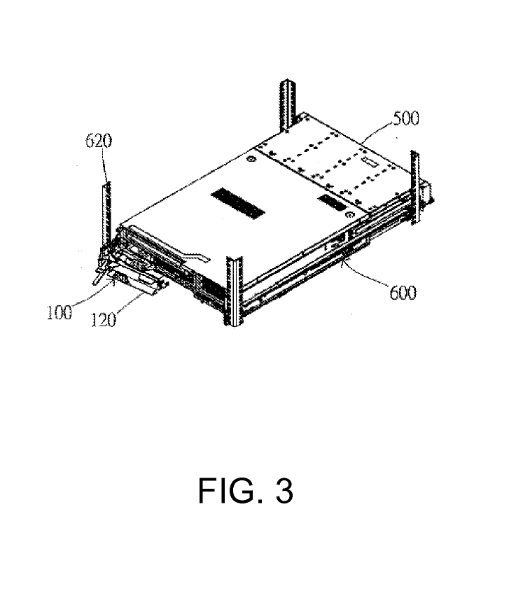

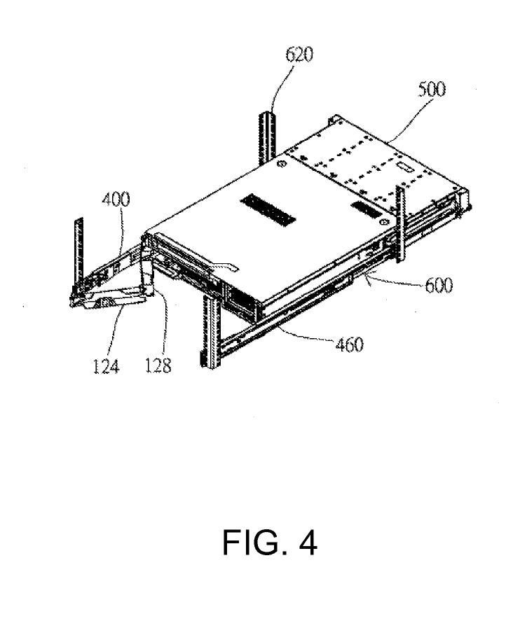

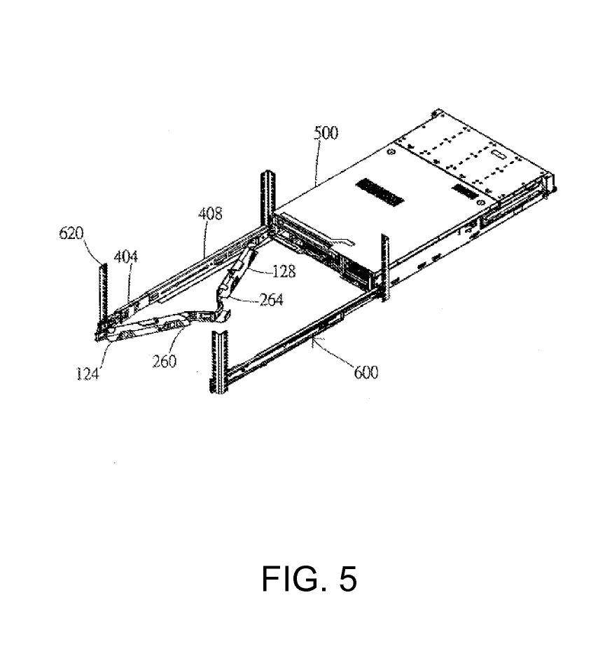

FIG. 1 is a perspective schematic view of a cable management device 100 according to an embodiment of the invention. FIG. 2 shows a half out configuration of the cable management device 100. FIG. 3 is a schematic view of a rack 600 of an electrical equipment unit (e.g., a server) 500 and the cable management device 100 folded in a half out configuration. FIG. 4 is a schematic view of the rack 600 and the cable management device 100 unfolded in a half out configuration. FIG. 5 is a schematic view of the rack 600 and the cable management device 100 in a full out configuration.

Referring to FIG. 1 through FIG. 5, and particularly to FIG. 4, in an embodiment of the invention, the cable management device 100 is disposed between two sliding rail devices 400, 460, which are correspondingly fixed to upright posts 620 of the rack 600. The aforementioned features and advantages of the invention are further illustrated herein.

Referring to FIG. 1, the cable management device 100 comprises a device body 120, a connecting member 140, and an extension body 160. The device body 120 comprises a first cable management arm 124 and a second cable management arm 128. The connecting member 140 is removable. The connecting member 140 pivotally connects a first end 132 of the first cable management arm 124 and a first end 136 of the second cable management arm 128 such that the cable management device 100 may be applied in a first cable management configuration.

In another aspect, once the connecting member 140 is removed, the first cable management arm 124 and the second cable management arm 128 are no longer connected. In such case, the first end 132 of the first cable management arm 124 and the first end 136 of the second cable management arm 128 may be connected to two opposing ends of the extension body 160, respectively, such that the cable management device 100 may be applied in a second cable management configuration.

In an embodiment, the extension body 160 comprises a third cable management arm 260 and a fourth cable management arm 264. The third cable management arm 260 and the fourth cable management arm 264 may be firmly connected via a connecting member 900. Alternatively, the connecting member 900, the first cable management arm 124, and the second cable management arm 128 may be integrally formed as a unitary structure—i.e., a U-shaped structure. However, the aforementioned embodiments are not intended to restrict the scope of the invention. The connecting member 900 has a carrying portion 910 for carrying a cable (not shown).

In response to removal of the connecting member 140, an end 268 of the third cable management arm 260 may be engaged with the first end 132 of the first cable management arm 124 via a first engaging device, and an end 272 of the fourth cable management arm 264 may be engaged with the first end 136 of the second cable management arm 128 via a second engaging device. The first engaging device comprises first engaging holes 284A, 284B located at the first cable management arm 124 and first engaging posts 276A, 276B located at the third cable management arm 260 which may be engaged with the first engaging holes 284A, 284B. The positions of the first engaging posts 276A, 276B and the first engaging holes 284A, 284B are interchangeable. The second engaging device comprises second engaging holes 288A, 288B located at the second cable management arm 128 and second engaging posts 280A, 280B located at the fourth cable management arm 264 which may be engaged with the second engaging holes 288A, 288B. The positions of the second engaging posts 280A, 280B and the second engaging holes 288A, 288B are interchangeable. Alternatively, the engaging devices may be designed in any other way; the aforementioned embodiments are not intended to restrict the scope of the invention. Due to the engaging holes and the engaging posts which operate in conjunction with each other, the third cable management arm 260 and the fourth cable management arm 264 are connected to the first cable management arm 124 and the second cable management arm 128, respectively.

Referring to FIG. 5, once the connecting member 140 is removed, the third cable management arm 260 and the fourth cable management arm 264 may be firmly connected to the first cable management arm 124 and the second cable management arm 128 via the first engaging device and the second engaging device, respectively, such that the cable management device 100 may be applied in the second cable management configuration.

As previously mentioned, the cable management device 100 is disposed between the two sliding rail devices 400, 460. According to an embodiment, the cable management device 100 is disposed between the first sliding rail device 400 and the opposing second sliding rail device 460 of the rack 600. Referring to FIG. 5, each of the first sliding rail device 400 and the second sliding rail device 460 comprises a first track 404 fixed to the rack 600 and a second track 408 slidably disposed on the first track 404. In one embodiment, the second track 408 has a substantially C-shaped cross-section and is slidably disposed around the first track 404 in a conventional manner. In another embodiment, the second track 408 is slidably disposed in the first track 404 in a conventional manner. Alternatively, the first track 404 and the second track 408 may be designed in any other way; the aforementioned embodiments are not intended to restrict the scope of the invention. The electrical equipment unit 500 is connected to the second track 408 of the first sliding rail device 400. The connection of the electrical equipment unit 500 and the second track 408 is achieved via screws or mechanical joggle joints. Hence, the second track 408 moves as the electrical equipment unit 500 is pushed into the chassis of the rack 600 or is withdrawn from the chassis. The first sliding rail device 400 and the second sliding rail device 460 are implemented via conventional sliding rail technology, and motion of the respective sliding rail devices against the chassis may be conventionally implemented.

Referring to FIG. 1, FIG. 4, and FIG. 5, in an embodiment, a second end 142 of the first cable management arm 124 and a second end 144 of the second cable management arm 128 are connected to the first track 404 and the second track 408 of the first sliding rail device 400, respectively. Accordingly, the device body 120 unfolds or folds as the first sliding rail device 400 and the second sliding rail device 460 protrude forward or retract backward (i.e., as the electrical equipment unit 500 moves forward or moves backward.)

Regarding the first sliding rail device 400, the second end 142 of the first cable management arm 124 is stationary and pivotally rotatable relative to the first track 404 via a first installation element 326 pivotally connected to the second end 142 of the first cable management arm 124 and engaged with the first track 404 of the first sliding rail device 400. In response to the extension of the second track 408, the second end 144 of the second cable management arm 128 moves and pivotally rotates via a second installation element 340 pivotally connected to the second end 144 of the second cable management arm 128 and engaged with the second track 408 of the first sliding rail device 400. In another embodiment, the operation of the first cable management arm 124, the second cable management arm 128, the first track 404, and the second track 408 may be designed in any other way; the aforementioned embodiments are not intended to restrict the scope of the invention.

Referring to FIG. 1, an engaging knob 292 is disposed on the first installation element 326, and the first installation element 326 is connected to a bending plate 320. The bending plate 320 may be connected to the first cable management arm 124. An engaging knob 296 is disposed on the second installation element 340, and the second installation element 340 is connected to a bending plate 324. The bending plate 324 may be connected to the second cable management arm 128. According to the aforementioned arrangement, the first installation element 326 and the second installation element 340 are located at two ends of the device body 120, respectively.

In one embodiment, the connecting member 140 may be a removable hinge (not shown). In response to removal of the hinge, the first cable management arm 124 and the second cable management arm 128 may be switched from a connected state to a disconnected state. In another embodiment, the connecting member 140 may be a removable spiral spring (not shown) having two ends fixed to the corresponding ends of the first cable management arm 124 and the second cable management arm 128, respectively. The spiral spring not only is used in pivotal connection, but also may be flexibly bent. In response to removal of the spiral spring, the first cable management arm 124 and the second cable management arm 128 may be switched from a connected state to a disconnected state.

The cable management device 100 further comprises a plurality of cable management hooks 700 disposed at the first cable management arm 124, the second cable management arm 128, and the extension body 160 for carrying a cable (not shown). In an embodiment, the cable management hooks 700 are integrally formed as a unitary structure and disposed on the first cable management arm 124, the second cable management arm 128, and the extension body 160. In another embodiment, each of the cable management hooks 700 comprises two parallel C-shaped holders connected at one end thereof. The other ends of the two C-shaped holders form a pair of fastening portions.

According to an embodiment of the invention, the first cable management configuration is a half out configuration, whereas the second cable management configuration is a full out configuration. Referring to FIG. 2, when the connecting member 140 pivotally connects the first cable management arm 124 and the second cable management arm 128, the cable management device 100 is at a half out cable management configuration (or first cable management configuration) characterized by limited internal space of the chassis of the rack 600. Referring to FIG. 3, when the electrical equipment unit 500 is fully inserted into the chassis, the cable management device 100 folds and draws closer to the rear end of the electrical equipment unit 500. Referring to FIG. 4, when the electrical equipment unit 500 is pulled out, the second cable management arm 128 moves together with the electrical equipment unit 500, and the first cable management arm 124 and the second cable management arm 128 which carry cables unfold. The cables are arranged in an orderly manner at any time and thus may be conveniently maintained by technicians.

Referring to FIG. 1 and FIG. 5, once the connecting member 140 is removed, the first cable management arm 124 and the second cable management arm 128 are no longer pivotally connected, and the third cable management arm 260 and the fourth cable management arm 264 are firmly connected to the first cable management arm 124 and the second cable management arm 128, respectively, such that the cable management device 100 is in a full out cable management configuration (or second cable management configuration) characterized by sufficient internal space of the rack chassis. Likewise, referring to FIG. 5, when the electrical equipment unit 500 is pulled out, the second cable management arm 128 and the fourth cable management arm 264 move together with the electrical equipment unit 500, and additionally the first cable management arm 124, the third cable management arm 260, the second cable management arm 128, and the fourth cable management arm 264 which carry cables move and unfold. Hence, the cables are arranged in an orderly manner at any time and thus may be conveniently maintained by technicians. Accordingly, the cable management device 100 is flexible and capable of unfolding and folding smoothly in every configuration.

The foregoing detailed description of the embodiments is used to further clearly describe the features and spirit of various embodiments of the invention. The foregoing description for each embodiment is not intended to limit the scope of the invention. All kinds of modifications made to the foregoing embodiments and equivalent arrangements should fall within the protected scope of the invention. Hence, the scope of the invention should be explained most widely according to the claims described thereafter in connection with the detailed description, and should cover all the possibly equivalent variations and equivalent arrangements.

What is claimed is:

1. A cable management device, comprising:
a device body comprising a first cable management arm and a second cable management arm;
a removable connecting member pivotally connecting a first end of the first cable management arm and a first end of the second cable management arm to attain a first cable management configuration; and
an extension body, wherein, in response to removal of the connecting member, two opposing ends of the extension body are respectively connected to the first end of the first cable management arm and the first end of the second cable management arm to attain a second cable management configuration.

2. The cable management device of claim 1, wherein the extension body comprises:
a third cable management arm; and
a fourth cable management arm, wherein, in response to removal of the connecting member, an end of the third cable management arm is engaged with the first end of the first cable management arm via a first engaging device and an end of the fourth cable management is engaged with the first end of the second cable management arm via a second engaging device.

3. The cable management device of claim 2, wherein the first engaging device comprises a first engaging hole and a first engaging post engaged with the first engaging hole, wherein the first engaging hole and the first engaging post are interchangeably disposed at the first cable management arm and the third cable management arm, respectively.

4. The cable management device of claim 2, wherein the second engaging device comprises a second engaging hole and a second engaging post engaged with the second engaging hole, wherein the second engaging hole and the second engaging post are interchangeably disposed at the second cable management arm and the fourth cable management arm, respectively.

5. The cable management device of claim 1, wherein the cable management device is disposed between a first sliding rail device and an opposing second sliding rail device of a rack, wherein each of the first sliding rail device and the second sliding rail device comprises a first track fixed to the rack and a second track slidably disposed on the first track.

6. The cable management device of claim 5, wherein a second end of the first cable management arm and a second end of the second cable management arm are connected to the first track of the first sliding rail device and the second track of the first sliding rail device, respectively, such that the device body unfolds or folds as the first sliding rail device protrudes forward or retracts backward.

7. The cable management device of claim 6, further comprising:
a first installation element pivotally connected to the second end of the first cable management arm and engaged with the first track of the first sliding rail device;
a second installation element pivotally connected to the second end of the second cable management arm and engaged with the second track of the first sliding rail device; and
a plurality of cable management hooks disposed at the first cable management arm, the second cable management arm, and the extension body for carrying a cable.

8. The cable management device of claim 1, wherein the first cable management configuration is a half out configuration of the cable management device, and wherein the second cable management configuration is a full out configuration of the cable management device.

9. The cable management device of claim 1, wherein the connecting member is a hinge, and wherein the first cable management arm and the second cable management arm are switched from a connected state to a disconnected state in response to removal of the hinge.

10. The cable management device of claim 1, wherein the connecting member is a spiral spring, wherein two ends of the spiral spring are connected to the first cable management arm and the second cable management arm, respectively, and wherein the first cable management arm and the second cable management arm are switched from a connected state to a disconnected state in response to removal of the spiral spring.

11. A rack assembly, comprising:
an electrical equipment rack comprising a sliding rail device;
an electrical equipment unit slidably disposed on the sliding rail device; and
a cable management device connected to the electrical equipment unit and the sliding rail device, the cable management device comprising:
a device body comprising a first cable management arm and a second cable management arm, wherein the first cable management arm and the second cable management arm unfolds or folds when the electrical equipment unit protrudes or retracts;
a removable connecting member pivotally connecting a first end of the first cable management arm and a first end of the second cable management arm to attain a first cable management configuration; and
an extension body wherein, in response to removal of the connecting member, two opposing ends of the extension body are respectively connected to the first end of the first cable management arm and the first end of the second cable management arm, to attain a second cable management configuration.

12. The rack assembly of claim 11, wherein the extension body of the cable management device comprises:
a third cable management arm; and
a fourth cable management arm, wherein, in response to removal of the connecting member, an end of the third cable management arm is engaged with the first end of the first cable management arm via a first engaging device and an end of the fourth cable management is engaged with the first end of the second cable management arm via a second engaging device.

13. The rack assembly of claim 12, wherein the first engaging device comprises a first engaging hole and a first engaging post engaged with the first engaging hole, wherein the first engaging hole and the first engaging post are interchangeably disposed at the first cable management arm and the third cable management arm, respectively.

14. The rack assembly of claim 12, wherein the second engaging device comprises a second engaging hole and a second engaging post engaged with the second engaging hole, wherein the second engaging hole and the second engaging post are interchangeably disposed at the second cable management arm and the fourth cable management arm, respectively.

15. The rack assembly of claim 11, wherein the sliding rail device comprises a first sliding rail and an opposing second sliding rail, wherein the cable management device is disposed between the first sliding rail and the sliding second rail, and wherein each of the first sliding rail and the second sliding rail comprises a first track fixed to the rack and a second track slidably disposed on the first track.

16. The rack assembly of claim 15, wherein a second end of the first cable management arm and a second end of the second cable management arm are connected to the first track of the first sliding rail and the second track of the first sliding rail, respectively, wherein the second end of the second cable management arm is connected to the electrical equipment unit such that the device body unfolds or folds as the first sliding rail protrudes forward or retracts backward.

17. The rack assembly of claim 16, wherein the cable management device further comprises:
a first installation element pivotally connected to the second end of the first cable management arm and engaged with the first track of the first sliding rail;
a second installation element pivotally connected to the second end of the second cable management arm and engaged with the second track of the first sliding rail; and
a plurality of cable management hooks disposed at the first cable management arm, the second cable management arm, and the extension body for carrying a cable.

18. The rack assembly of claim 11, wherein the first cable management configuration is a half out configuration of the cable management device, and wherein the second cable management configuration is a full out configuration of the cable management device.

19. The rack assembly of claim 11, wherein the connecting member of the cable management device is a hinge, and wherein the first cable management arm and the second cable management arm are switched from a connected state to a disconnected state in response to removal of the hinge.

20. The rack assembly of claim 11, wherein the connecting member of the cable management device is a spiral spring, wherein two ends of the spiral spring are connected to the first cable management arm and the second cable management arm, respectively, and wherein the first cable management arm and the second cable management arm are switched from a connected state to a disconnected state in response to removal of the spiral spring.
